(19) United States
(12) Patent Application Publication
(10) Pub. No.: US 2007/0190721 A1
(43) Pub. Date: Aug. 16, 2007

(54) Semiconductor memory device having an alloy metal gate electrode and method of manufacturing the same

(75) Inventors: Young-kwan Cha, Suwon-si (KR); Young-soo Park, Suwon-si (KR); Kwang-soo Seol, Suwon-si (KR); Sang-jin Park, Yongin-si (KR); Sang-min Shin, Seoul (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/655,180

(22) Filed: Jan. 19, 2007

(30) Foreign Application Priority Data
Feb. 16, 2006 (KR) 10-2006-0015149

(51) Int. Cl. H01L 21/336

(52) U.S. Cl. 438/257

(57) ABSTRACT

A semiconductor memory device having an alloy gate electrode layer and method of manufacturing the same are provided. The semiconductor memory device may include a semiconductor substrate having a first impurity region and a second impurity region. The semiconductor memory device may include a gate structure formed on the semiconductor substrate and contacting the first and second impurity regions. The gate structure may include an alloy gate electrode layer formed of a first metal and a second metal. The first metal may be a noble metal. The second metal may include at least one of aluminum (Al) and titanium (Ti), gallium (Ga), indium (In), tin (Sb), thallium (Tl), bismuth (Bi) and lead (Pb).

### PRIORITY STATEMENT

This application claims the benefit of priority from Korean Patent Application No. 10-2006-0015149, filed on Feb. 16, 2006 in the Korean Intellectual Property Office, the disclosure of which is incorporated herein in its entirety by reference.

### BACKGROUND

1. Field of the Invention

Example embodiments relate to a semiconductor memory device having an alloy gate electrode and method of manufacturing the same. Other example embodiments relate to a semiconductor memory device having an alloy gate electrode with a work function higher than a work function of n⁺ polysilicon and method of manufacturing the same.

2. Description of the Related Art

The performance of semiconductor memory devices increases as semiconductor memory devices are developed having more information storage capacity and higher speeds for recording and erasing information. A memory device may include a large number of memory unit cells connected in a circuit manner. The memory device may have an information storage capacity proportional to the number of memory cells per unit area, also known as the integration degree of memory.

Semiconductor process technologies are being developed to increase the integration degree of a semiconductor memory device. Semiconductor memory devices are being manufactured with new shapes and operating principles (e.g., the development of semiconductor memory devices having a Giant Magneto-Resistance (GMR) structure or a Tunneling Magneto-Resistance (TMR) structure on a transistor). New types of non-volatile semiconductor memory devices (e.g., a Phase-change Random Access Memory (PRAM)) that use phase transition material characteristics or a Semiconductor-Oxide-Nitride-Oxide-Semiconductor (SONOS) having a tunneling oxide layer, a charge trapping layer and a blocking oxide layer have recently been manufactured.

FIG. 1A is a diagram illustrating a cross-sectional view of a conventional charge trapping memory device.

Referring to FIG. 1A, a first impurity region 11a and a second impurity region 11b, which are doped with impurities, may be formed in a semiconductor substrate 10. If the semiconductor substrate 10 is a p-type, then the first and second impurity regions 11a and 11b may be doped with n-type impurities. A channel region (not shown) may be formed between the first and second impurity regions 11a and 11b in the semiconductor substrate 10. A gate structure 16 may be formed on the semiconductor substrate 10. The gate structure 16 may include a tunneling layer 12, a charge trapping layer 13 (formed of a dielectric material such as a nitride (e.g., silicon nitride (Si₃N₄)), a blocking layer 14 and a gate electrode layer 15 formed of a conductive material, sequentially stacked.

Information may be recorded when electric charges in the channel region pass through the tunneling layer 12 and are injected into the charge trapping layer 13 having a trap site. The blocking layer 14 may prevent electrons from running into the gate electrode layer 15 and electrons may be trapped by a trap site in the charge trapping layer 13. The blocking layer 14 may prevent electric charges in the gate electrode layer 15 from being injected into the charge trapping layer 13.

FIG. 1B is an energy band diagram of electrons passing through a blocking oxide layer from a gate electrode layer and tunneling into a charge trapping layer during an erasing operation of a conventional memory device.

As illustrated in FIG. 15, if a higher negative voltage is applied to the gate electrode 15 of the memory device for data erasing, then electric charges in the gate electrode layer 15 may be tunneled into the charge trapping layer 13 (a second (II) region) via the blocking layer 14 (a first (I) region) by a phenomenon known as back tunneling.

Tunneled negative charges may shift a threshold voltage of a transistor structure in the direction of an anode. Shifting of the threshold voltage of the transistor structure may occur frequently if the gate electrode layer 15 is formed of a material having a relatively low work function. As such, it may be difficult to prevent back tunneling from occurring in a conventional n⁺ polysilicon gate structure.

The gate electrode layer 15 may be formed of a material having a higher work function. If a material having a higher work function is used, then it may be possible to block electric charges tunneling from the gate electrode layer 15 by increasing the height of an energy barrier, Φ_{M1}, of the first (I) region as shown in FIG. 1B.

If a material having a higher work function employed, then the adhesive strength between the gate electrode layer 15 and the blocking layer 14 formed of an oxide (e.g., silicon dioxide (SiO₂)) may decrease. For example, a work function of 5.27 eV for iridium (Ir) may be significantly higher than a work function of 4.1 eV for n⁺ polysilicon. If an iridium (Ir) thin layer is formed on the blocking layer 14 to prevent back tunneling, then the adhesive strength between the iridium (Ir) thin layer and the blocking layer 14 may decrease.

FIG. 1C is an image showing the result of a test in which an iridium (Ir) thin layer was deposited on an oxide layer and the adhesive strength between the iridium (Ir) thin layer and the oxide layer was measured using a taping method according to conventional methods.

Referring to FIG. 1C, a test specimen may be obtained by depositing an silicon dioxide (SiO₂) oxide layer on a silicon (Si) substrate to a thickness of about 100 nm. An iridium (Ir) layer may be deposited on the SiO₂ oxide layer to a thickness of about 100 nm. If a tape for testing is attached to the iridium (Ir) layer and separated from the iridium (Ir) layer, then the iridium (Ir) layer and the SiO₂ oxide layer may be separated from each other. Because the adhesive characteristics between the blocking layer 14 and the gate electrode layer 15 are not good, it may be difficult for the blocking layer 14 and the gate electrode layer 15 to act as a gate electrode.

### SUMMARY

Example embodiments relate to a semiconductor memory device having an alloy gate electrode and method of manufacturing the same. Other example embodiments relate to a semiconductor memory device having an alloy gate electrode with a work function higher than a work function of n⁺ polysilicon and method of manufacturing the same.

Example embodiments provide a semiconductor memory device having an alloy gate electrode capable of reducing or preventing back tunneling of electrons into a charge trapping layer from a gate electrode layer while demonstrating good adhesive characteristics between a blocking layer and the gate electrode layer.

According to example embodiments, there is provided a semiconductor memory device having an alloy gate electrode layer. The semiconductor memory device may include a semiconductor substrate having a first impurity region and a second impurity region. A gate structure may be formed on the semiconductor substrate and contacting the first and second impurity regions. The gate structure may include an alloy gate electrode layer formed of a first metal and a second metal. The first metal may be a noble metal. The second metal may include a transition or post-transition metal. The noble metal may be platinum (Pt) and/or iridium (Ir). The second metal may be aluminum (Al) titanium (Ti), gallium (Ga), indium (In), tin (Sb), thallium (Tl), bismuth (Bi) and/or lead (Pb).

According to other example embodiments, the first metal may be an energy-barrier-increasing metal in a first region. The second metal may be an adhesive-increasing metal in a second region, wherein the adhesive-increasing metal increases adhesive characteristics of the first region.

The gate structure may be a stack structure in which a tunneling layer, a charge trapping layer, a blocking layer and the alloy gate electrode layer are sequentially deposited (or formed). The tunneling layer and the blocking layer may be formed of silicon dioxide (SiO₂). The charge trapping layer may be formed of aluminum oxide (Al₂O₃), hafnium oxide (HfO) or silicon nitride (Si₃N₄).

The gate structure may include the first region, a second region and a third region. The first region may include the blocking layer. The second region may include the charge trapping layer. The third region may include the tunneling layer.

According to other example embodiments, there is provided a method of fabricating a semiconductor memory device having an alloy gate electrode layer. The method may include sequentially forming a tunneling layer, a charge trapping layer and a blocking layer on a semiconductor substrate; forming an alloy gate electrode layer on the blocking layer; exposing edge surfaces of the semiconductor substrate by etching side surfaces of the tunneling layer, the charge trapping layer, the blocking layer and the gate electrode layer; and forming a first impurity region and a second impurity region by doping the exposed edge surfaces of the semiconductor substrate. The alloy gate electrode layer may include a first metal and a second metal. The first metal may be a noble metal. The second metal may include at least one of aluminum (Al), titanium (Ti), gallium (Ga), indium (In), tin (Sb), thallium (Tl), bismuth (Bi) and lead (Pb).

The method may further include forming a first region, a second region and a third region. The first region may include the blocking layer. An energy barrier of the first region may be increased by the first metal. The second metal may increase adhesive characteristics of the first region.

The second region may include the charge trapping layer and the third region may include the tunneling layer.

The tunneling layer and the blocking layer may be formed of silicon dioxide (SiO₂). The charge trapping layer may be formed of aluminum oxide (Al₂O₃), hafnium oxide (HfO) or silicon nitride (Si₃N₄).

Forming the gate electrode layer may include forming the gate electrode layer by co-sputtering the first and second metals as a single target.

Forming the gate electrode layer may include individually sputtering the first and second metals to form an alloy target.

### BRIEF DESCRIPTION OF THE DRAWINGS

Example embodiments will be more clearly understood from the following detailed description taken in conjunction with the accompanying drawings. FIGS. 1-5 represent non-limiting, example embodiments as described herein.

FIG. 1A is a diagram illustrating a cross-sectional view of a conventional memory device;

FIG. 1B is an energy band diagram of electrons passing through a blocking oxide layer from a gate electrode layer and tunneling into a charge trapping layer during an erasing operation of a conventional memory device;

FIG. 1C is an image showing the result of a test in which an iridium (Ir) thin layer was deposited on an oxide layer and the adhesive strength between the iridium (Ir) thin layer and the oxide layer was measured according to a conventional taping method;

FIG. 2A a diagram illustrating a cross-sectional view of a semiconductor memory device having an alloy gate electrode layer according example embodiments;

FIG. 2B is an energy band diagram of electrons passing through a blocking oxide layer from a gate electrode layer and tunneling into a charge trapping layer during an erasing operation of a semiconductor memory device having an alloy gate electrode layer according to example embodiments;

FIGS. 3A through 3E are diagrams illustrating cross-sectional views of a method of fabricating a semiconductor memory device having an alloy gate electrode layer according to example embodiments;

FIG. 4A is an image showing the results of a test measuring the adhesive strength between an iridium titanium (IrTi) alloy layer and an oxide layer formed according to example embodiments;

FIG. 4B is a graph illustrating a work function value of an iridium titanium (IrTi) alloy according to example embodiments; and

FIG. 5 is a graph illustrating work function values of various metal materials according to example embodiments.

### DETAILED DESCRIPTION OF EXAMPLE EMBODIMENTS

Various example embodiments will now be described more fully with reference to the accompanying drawings in which some example embodiments are shown. In the drawings, the thicknesses of layers and regions may be exaggerated for clarity.

Detailed illustrative embodiments are disclosed herein. However, specific structural and functional details disclosed herein are merely representative for purposes of describing example embodiments. This invention may, however, may be embodied in many alternate forms and should not be construed as limited to only the example embodiments set forth herein.

Accordingly, while the example embodiments are capable of various modifications and alternative forms, embodiments thereof are shown by way of example in the drawings and will herein be described in detail. It should be understood, however, that there is no intent to limit example embodiments to the particular forms disclosed, but on the contrary, the example embodiments are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the example embodiments. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the scope of the example embodiments.

Spatially relative terms, such as “beneath,” “below,” “lower,” “above,” “upper” and the like, may be used herein for ease of description to describe one element or a relationship between a feature and another element or feature as illustrated in the figures. It will be understood that the spatially relative terms are intended to encompass different orientations of the device in use or operation in addition to the orientation depicted in the Figures. For example, if the device in the figures is turned over, elements described as “below” or “beneath” other elements or features would then be oriented “above” the other elements or features. Thus, for example, the term “below” can encompass both an orientation which is above as well as below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In order to more specifically describe example embodiments, various aspects will be described in detail with reference to the attached drawings. However, the present invention is not limited to the example embodiments described.

Example embodiments relate to a semiconductor memory device having an alloy gate electrode and method of manufacturing the same. Other example embodiments relate to a semiconductor memory device having an alloy gate electrode with a work function higher than a work function of n⁺ polysilicon and method of manufacturing the same.

Hereinafter, a semiconductor memory device having an alloy gate electrode layer according to example embodiments will be described in detail with reference to the accompanying drawings.

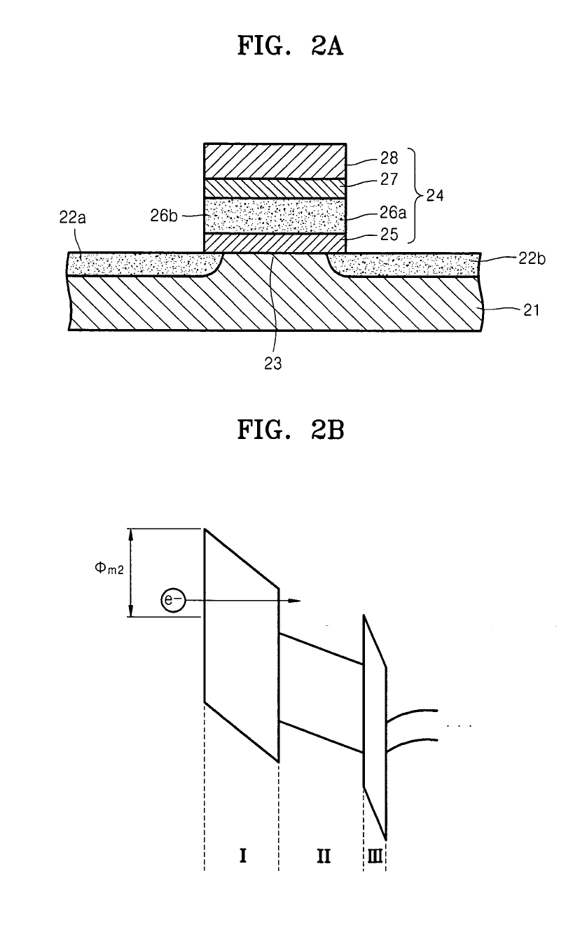

FIG. 2A is a diagram illustrating a cross-sectional view of a semiconductor memory device having an alloy gate electrode layer according to example embodiments.

Referring to FIG. 2A, a first impurity region 22a and a second impurity region 22b, both regions doped with impurities, may be formed in a semiconductor substrate 21. A channel region 23 may be formed between the first impurity region 22a and the second impurity region 22b in the semiconductor substrate 21. A gate structure 24 may be formed on the semiconductor substrate 21. The gate structure 24 may contact the first and second impurity regions 22a and 22b. The gate structure 24 may be a stack structure in which a tunneling layer 25, a charge trapping layer 26a, a blocking layer 27 and a gate electrode layer 28 may be sequentially formed.

Example materials that may be used to fabricate each layer of the semiconductor memory device illustrated in FIG. 2A will now be described.

The tunneling layer 25 and the blocking layer 27 may be formed of an insulating material (e.g., silicon dioxide (SiO₂). The charge trapping layer 26a may be formed of a material having a higher dielectric constant than silicon dioxide (SiO₂). The charge trapping layer 26a may be formed of aluminum oxide (Al₂O₃), hafnium oxide (HfO), or silicon nitride (Si₃N₄). The charge trapping layer 26a may include a trap site 26b that stores electrons passing through the tunneling layer 25.

The gate electrode layer 28 may be formed of a material having relatively high conductibility and a work function higher than n⁺ polysilicon. A work function indicates the amount of energy needed to separate electrons from a material. The gate electrode layer 28 may be formed of a metal alloy. The metal alloy may be an alloy formed of a noble metal material (e.g., platinum (Pt), iridium (Ir) or a similar metal) having a work function of 5.1 eV or higher and a transition or post-transition metal material (e.g., aluminum (Al), titanium (Ti), gallium (Ga), indium (In), tin (Sb), thallium (Tl), bismuth (Bi), lead (Pb) or similar metal) having increased adhesive characteristics with an oxide layer.

FIG. 2B is an energy band diagram of electrons passing through a blocking oxide layer from a gate electrode layer and tunneling into a charge trapping layer during an erasing operation of a semiconductor memory device having an alloy gate electrode layer according to example embodiments.

Referring to FIG. 2B a first (I) region may be a blocking layer, a second (II) region may be a charge trapping layer and a third (III) region may be a tunneling layer.

Use of the Fowler-Nordheim (FN) method to remove electric charges accumulated in a charge trapping layer of a semiconductor memory device will now be described.

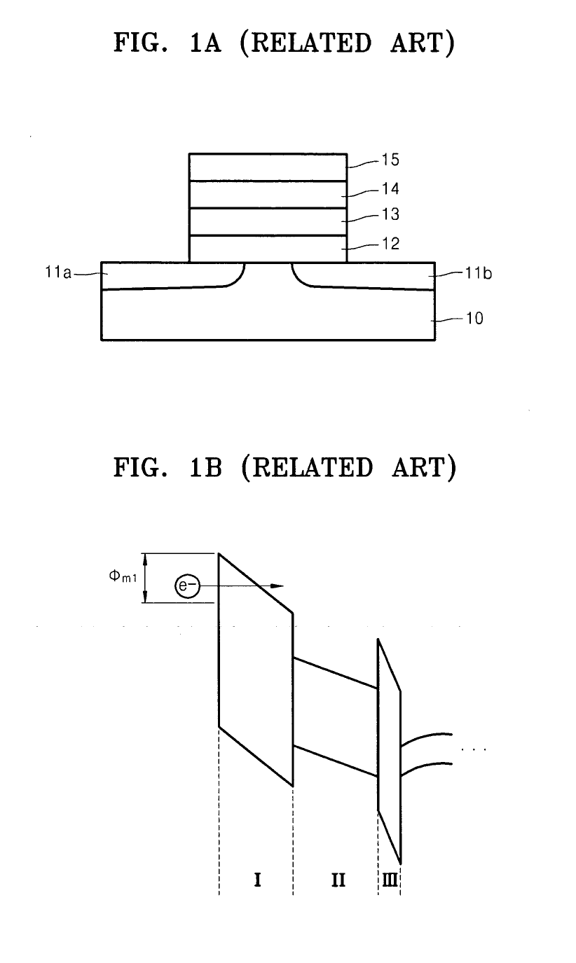

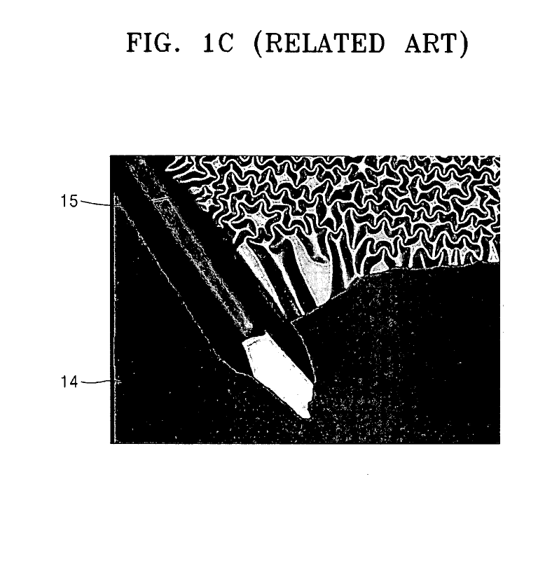

As illustrated in FIG. 1B, if n⁺ polysilicon having a work function of 4.1 eV is used as a gate electrode layer, then power is supplied via a gate electrode layer according to conventional methods. As such, back tunneling of electrons into a second (II) is likely to occur because an energy barrier of a first (I) region may be low.

Referring to FIG. 2B, the height of an energy barrier, Φ_{M2}, may be increased by using a material having a high work function (e.g., 5.1 eV or higher) as a gate electrode layer, reducing or preventing back tunneling. The height of the energy barrier, Φ_{M2}, according to example embodiments may be higher than the height of the energy barrier, Φ_{M1}, observed in the conventional art. If electric charges in the gate electrode layer are injected into a charge trapping layer, only direct tunneling may occur. The likelihood of direct tunneling occurring may be lower than the likelihood of back tunneling occurring. As such, it may be possible to reduce or prevent back tunneling from occurring in a semiconductor memory device according to example embodiments.

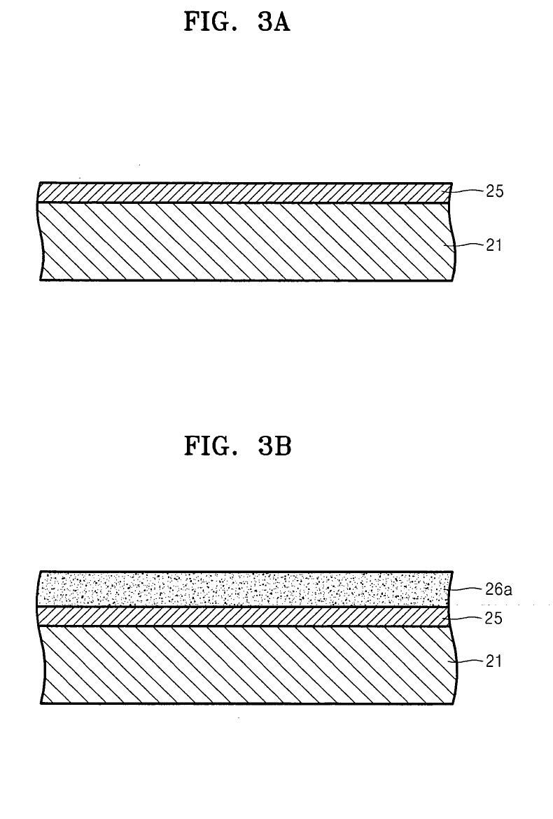

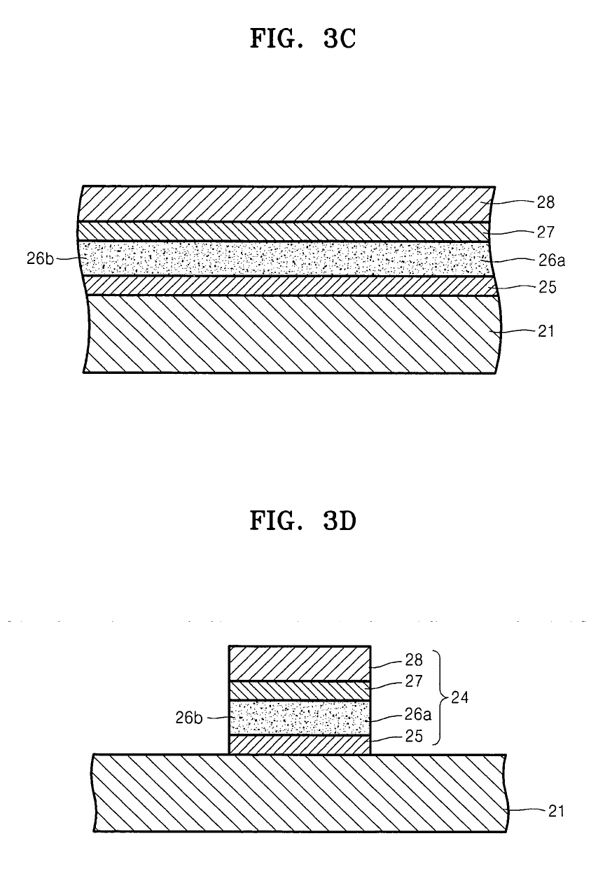

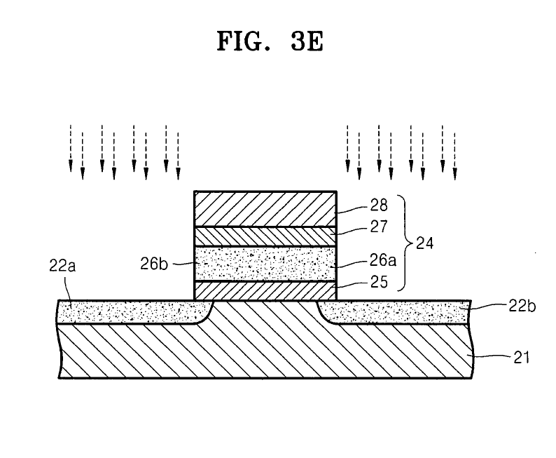

FIGS. 3A through 3E are diagrams illustrating cross-sectional views of a method of fabricating a semiconductor memory device having an alloy gate electrode layer according to example embodiments.

Referring to FIGS. 3A and 3B, a tunneling layer 25, a charge trapping layer 26a, and a blocking layer 27 may be sequentially formed on a semiconductor substrate 21 through a chemical vapor deposition (CVD) process or an atomic layer deposition (ALD) process. The tunneling layer 25 may be formed of an insulating material (e.g., silicon oxide (SiO₂)). The charge trapping layer 26a may be formed of a high-k material (e.g., aluminum oxide (Al₂O₃), hafnium oxide (HfO) or silicon nitride (Si₃N₄)), which is a material having a high dielectric constant.

Referring to FIG. 3C, a gate electrode layer 28 may be formed on the blocking layer 27 by making an alloy of a noble metal material (e.g., iridium (Ir) or platinum (Pt)) that has a higher work function and a transition or post-transition metal material (e.g., aluminum (Al), titanium (Ti), gallium (Ga), indium (In), tin (Sb), thallium (Tl), bismuth (Bi) or lead (Pb)) that has increased adhesive characteristics with the blocking layer 27. The alloy may be formed by co-sputtering on each of the noble metal material and the transition (or post-transition) metal material as a single target. The gate electrode layer 28 may be formed by sputtering (not co-sputtering) on each of the noble metal material and the transition (or post-transition) metal material as a single target in the form of an alloy target.

Referring to FIG. 3D, a gate structure 24 may be obtained (or formed) by etching side surfaces of the tunneling layer 25, the charge trapping layer 26a, the blocking layer 27 and the gate electrode layer 28, exposing edge surfaces of the semiconductor substrate 21.

Referring to FIG. 3E, a first impurity region 22a and a second impurity region 22b may be formed by doping exposed edge surfaces of the semiconductor substrate 21 using an impurity dopant. The first and second impurity regions 22a and 22b may be thermally processed to be activated.

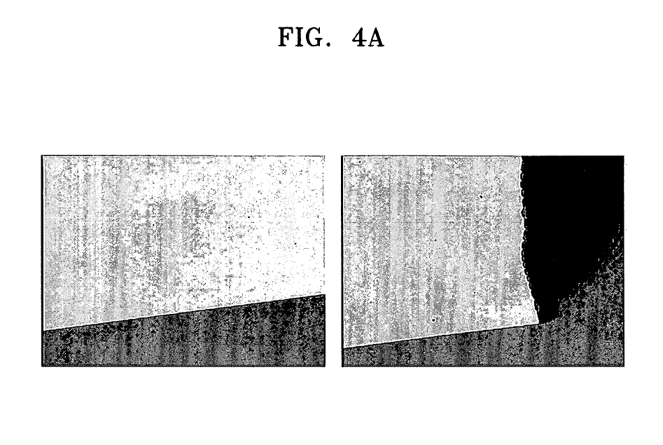

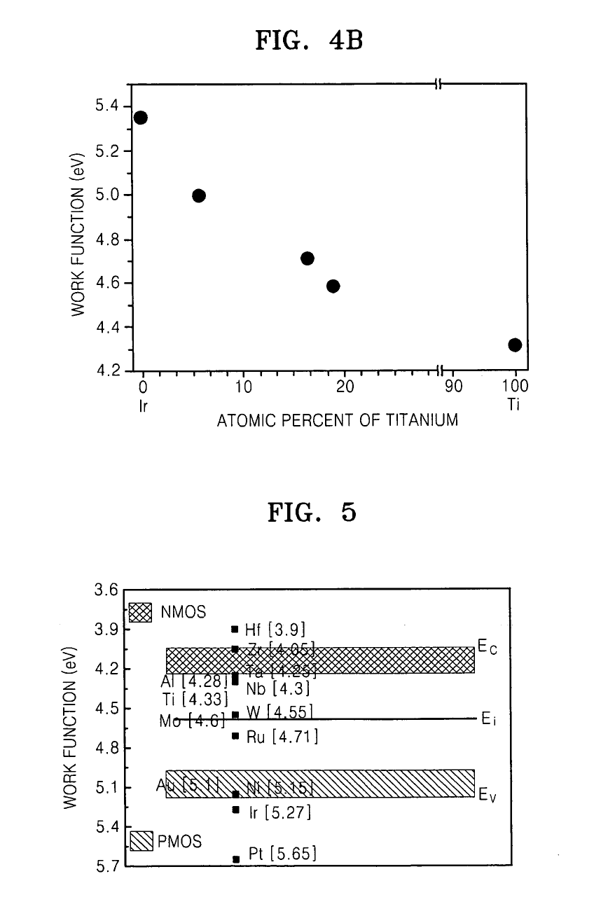

FIG. 4A is an image showing the results of a test measuring the adhesive strength between an iridium titanium (IrTi) alloy layer and an oxide layer formed according to example embodiments.

Referring to FIG. 4A, the iridium titanium (IrTi) alloy thin layer was deposited as gate electrode layer on a blocking layer formed of an oxide (e.g., silicon dioxide SiO₂). The adhesive strength between the gate electrode layer and the blocking layer was measured using a taping method.

The images show that the iridium titanium (IrTi) alloy thin layer demonstrates increased adhesive characteristics with the oxide. As shown in the image in FIG. 1C, the adhesive characteristics between a gate electrode layer and a barrier layer may be very poor when the gate electrode layer is formed of only iridium (Ir). As shown in the images in FIG. 4A, the adhesive characteristics may improve if a gate electrode layer is formed of an iridium titanium (IrTi) alloy.

FIG. 4B is a graph illustrating a work function value of an iridium titanium (IrTi) alloy according to example embodiments. The iridium titanium (IrTi) alloy was used a gate electrode layer.

Referring to FIG. 4B, the work function value of pure titanium (Ti) is 4.33 eV. The work function value of pure iridium (Ir) is 5.27 eV. The higher the ratio of iridium (Ir) to titanium (Ti) in the iridium titanium (IrTi) alloy, the greater the work function value. It may be possible to adjust the work function value of a gate electrode by controlling a composition of the iridium titanium (IrTi) alloy.

FIG. 5 is a graph illustrating work function values of various metal materials according to example embodiments.

Referring to FIG. 5, a gate electrode may be formed by making an alloy with iridium (Ir) or platinum (Pt) having a higher work function value and aluminum (Al) titanium (Ti), gallium (Ga), indium (In), tin (Sb), thallium (Tl), bismuth (Bi) or lead (Pb) having a low work function and increased adhesive characteristics with an oxide.

According to example embodiments, it may be possible to prevent back tunneling by forming a gate electrode layer of a material having a higher work function without significantly increasing the thickness of a blocking layer. Even if a metal material (e.g., iridium (Ir) or platinum (Pt) having a higher work function is used to form a gate electrode layer, then it may be possible to increase the adhesive characteristics between the gate electrode layer and an oxide.

While this invention has been particularly shown and described with reference to example embodiments thereof, it will be understood by those skilled in the art that various changes in form and details may be made therein without departing from the spirit and scope of the invention as defined by the appended claims. For example, the present invention is applicable to not only a charge trapping memory device but also a floating gate type flash memory device.

What is claimed is:

1. A semiconductor memory device, comprising:
a semiconductor substrate having a first impurity region and a second impurity region; and
a gate structure including an alloy gate electrode layer, wherein the gate structure is formed on the semiconductor substrate and contacts the first and second impurity regions,
wherein the alloy gate electrode layer is formed of a first metal and a second metal, wherein the first metal is a noble metal and the second metal includes a transition or post-transition metal selected from at least one of aluminum (Al), titanium (Ti), gallium (Ga), indium (In), tin (Sb), thallium (Tl), bismuth (Bi) and lead (Pb).

2. The semiconductor memory device of claim 1, wherein the gate structure is a stack structure including a tunneling layer, a charge trapping layer, a blocking layer and the alloy gate electrode layer sequentially stacked.

3. The semiconductor memory device of claim 2, wherein the tunneling layer and the blocking layer are formed of silicon dioxide (SiO₂), and the charge trapping layer is formed of aluminum oxide (Al₂O₃), hafnium oxide (HfO) or silicon nitride (Si₃N₄).

4. The semiconductor memory device of claim 1, wherein the noble metal is at least one of platinum (Pt) or iridium (Ir).

5. The semiconductor memory device of claim 1, wherein the first metal is an energy-barrier-increasing metal in a first region and the second metal is an adhesive-increasing metal in a second region, wherein the adhesive-increasing metal increases adhesive characteristics of the first region.

6. The semiconductor memory device of claim 5, wherein the gate structure includes the first region, the second region and a third region sequentially stacked, wherein the first region includes a blocking layer, the second region includes a charge trapping layer and the third region includes a tunneling layer, further wherein the alloy gate electrode layer is formed on the third region.

7. The semiconductor memory device of claim 6, wherein the tunneling layer and the blocking layer are formed of silicon dioxide (SiO₂), and the charge trapping layer is formed of aluminum oxide (Al₂O₃), hafnium oxide (HfO) or silicon nitride (Si₃N₄).

8. The semiconductor memory device of claim 5, wherein the noble metal is at least one of platinum (Pt) or iridium (Ir).

9. A method of fabricating a semiconductor memory device, comprising:
sequentially forming a tunneling layer, a charge trapping layer and a blocking layer on a semiconductor substrate;
forming an alloy gate electrode layer of a first metal and a second metal on the blocking layer, where the first metal is a noble metal and the second metal includes a transition or post-transition metal selected from at least one of aluminum (Al), titanium (Ti), gallium (Ga), indium (In), tin (Sb), thallium (Tl), bismuth (Bi) and lead (Pb);
exposing at least one edge surface of the semiconductor substrate by etching at least one side surface of the tunneling layer, the charge trapping layer, the blocking layer and the alloy gate electrode layer; and
forming a first impurity region and a second impurity region by doping the at least one exposed edge surface of the semiconductor substrate.

10. The method of claim 9, wherein the tunneling layer and the blocking layer are formed of silicon oxide (SiO₂), and the charge trapping layer is formed of aluminum oxide (Al₂O₃), hafnium oxide (HfO) or silicon nitride (Si₃N₄).

11. The method of claim 9, wherein the noble metal is at least one of platinum (Pt) or iridium (Ir).

12. The method of claim 9, wherein forming the gate electrode layer includes co-sputtering the first and second metals as a single target.

13. The method of claim 9, wherein forming the gate electrode layer includes individually sputtering the first and second metals to form an alloy target.

14. The method of claim 9, further comprising:
forming a first region, a second region and a third region, wherein the blocking layer is in the first region, the charge trapping layer is in the second region and the tunneling layer is in the third region.

15. The method of claim 14, wherein the first metal increases an energy barrier of the first region, and the second metal increases adhesive characteristics of the first region.

16. The method of claim 15, wherein increasing the energy barrier of the first region prevents electrons from the gate electrode layer from tunneling into the second region.

17. The method of claim 14, wherein the tunneling layer and the blocking layer are formed of silicon oxide (SiO₂), and the charge trapping layer is formed of aluminum oxide (Al₂O₃), hafnium oxide (HfO) or silicon nitride (Si₃N₄).

18. The method of claim 14, wherein the noble metal is at least one of platinum (Pt) or iridium (Ir).
